(19) United States
(12) Patent Application Publication
(10) Pub. No.: US 2023/0260854 A1
(43) Pub. Date: Aug. 17, 2023

(54) WAFER PROCESSING METHOD

(71) Applicant: DISCO CORPORATION, Tokyo (JP)

(72) Inventors: Masatoshi WAKAHARA, Tokyo (JP); Kentaro ODANAKA, Tokyo (JP); Heidi LAN, Tokyo (JP)

(21) Appl. No.: 18/168,827

(22) Filed: Feb. 14, 2023

(30) Foreign Application Priority Data
Feb. 16, 2022 (JP) 2022-022122

(51) Int. Cl. H01L 21/66; H01L 21/78; H01L 21/683

(52) U.S. Cl. CPC H01L 22/12; H01L 21/78; H01L 21/6836; H01L 2221/68327; H01L 2221/68386

(57) ABSTRACT

A wafer processing method for processing a wafer having a front surface on which a pattern and a plurality of crossing planned dividing lines are formed, along the planned dividing lines. The method includes holding the front surface of the wafer by a holding table, detecting the planned dividing lines on the front surface from a side of the front surface through the holding table or from a side of a back surface by using an infrared camera and processing the wafer by using a processing unit from the side of the back surface along the planned dividing lines, and an inspection step of placing the wafer on an inspection table and inspecting processing quality from the back surface after the processing step. In the inspection step, a defective portion is stored on a basis of a characteristic point such as a notch.

### BACKGROUND OF THE INVENTION

### Field of the Invention

The present invention relates to a wafer processing method by which a wafer is divided.

### Description of the Related Art

In a process of dividing a wafer on a front surface of which device regions marked out by a plurality of planned dividing lines that intersect are formed, there is a step of placing the wafer on an inspection table and inspecting whether or not a defective portion is absent, after the division. In the case of executing inspection from the front surface side of the wafer in this inspection step, at which coordinate position in the wafer a defective chip exists is stored on the basis of a mark for alignment or the like formed on the front surface. However, in the case of executing inspection from a back surface side of the wafer, it is impossible to see the mark that exists on the front surface and serves as the basis. Therefore, inspection is executed while imaging is executed from the front surface side through the inspection table when the inspection table is transparent, and inspection is executed while devices on the front surface are imaged from the back surface side by an infrared (IR) camera when the inspection table is not transparent (for example, refer to Japanese Patent Laid-open No. 2012-113635 and Japanese Patent Laid-open No. 2012-227251).

### SUMMARY OF THE INVENTION

However, in the case of using an inspecting unit incapable of imaging through an inspection table or an inspecting unit that is not equipped with an IR camera, there is a problem that it is impossible to store a defective portion in association with the mark formed on the front surface. Hence, there is problem that, even when a defective portion can be identified in an inspecting apparatus, the defective portion becomes unknown due to conveyance deviation and the defective portion is erroneously recognized when the wafer is conveyed to another step.

Accordingly, an object of the present invention is to provide a wafer processing method that, even in the case of inspecting a wafer from a back surface thereof, allows storing of the position of a defective portion in the wafer and allows the defective portion to be identified also in another step.

In accordance with an aspect of the present invention, there is provided a wafer processing method for processing a wafer having a front surface on which a pattern and a plurality of planned dividing lines are formed, along the planned dividing lines, the wafer processing method including a holding step of holding the front surface of the wafer by a holding table, a processing step of detecting the planned dividing lines on the front surface from a side of the front surface through the holding table or from a side of a back surface by using an infrared camera and processing the wafer by using a processing unit from the side of the back surface along the planned dividing lines, and an inspection step of placing the wafer on an inspection table and inspecting processing quality from the back surface after the processing step. In the inspection step, a defective portion is stored on a basis of a characteristic point that the wafer has.

Preferably, as the characteristic point, there is a notch, an orientation flat, or a center point of the wafer, for example.

Preferably, when the wafer processing method further includes an inspection mark forming step of forming an inspection mark on the back surface by using the processing unit on the basis of an alignment mark formed on the front surface, the inspection mark is used as the characteristic point.

Preferably, any of a dividing groove that divides the wafer, a processed groove that does not divide the wafer, or a modified layer formed inside the wafer is formed in the processing step and the inspection mark forming step.

Preferably, when the processing step includes a protective film forming step of forming a protective film on the back surface of the wafer, an exposure step of removing the protective film formed along the planned dividing lines, by using the processing unit, to expose the planned dividing lines after the protective film forming step, and an etching step of executing plasma etching from the back surface to process the wafer along the planned dividing lines after the exposure step, the inspection mark forming step removes the protective film at a freely-selected position in a manner corresponding to a shape of the inspection mark, by using the processing unit, and forms the inspection mark on the back surface of the wafer in the etching step.

Preferably, the wafer processing method further includes a protective member forming step of forming a first protective member on the front surface before the processing step and a transfer step of forming a second protective member on the back surface and peeling off the first protective member from the front surface after the inspection step.

In the present invention, in the inspection step of inspecting the processing quality from the back surface, the defective portion is stored on the basis of the characteristic point that the wafer has. A design such as an alignment mark that serves as the basis for identifying the position of the defective portion does not exist on the back surface, unlike on the front surface. However, by storing the position of the defective portion on the basis of the characteristic point that the wafer has, the position of the defective portion can be stored in association with the characteristic point in the wafer without imaging the front surface side. Therefore, the defective portion can be identified on the basis of the characteristic point of the wafer also in another step.

By using a notch, an orientation flat, or a center point of the wafer as the characteristic point, the characteristic point formed in the semiconductor wafer can be used, and therefore, there is no need to form the characteristic point for inspection.

Further, by forming the inspection mark on the back surface on the basis of the alignment mark on the front surface, the defective portion can be stored on the basis of the inspection mark on the back surface without checking an image of the front surface, and the defective portion can be identified on the basis of the inspection mark also in another step.

The processing step includes the protective film forming step, the exposure step, and the etching step. In the inspection mark forming step, the protective film is removed in a manner corresponding to the shape of the inspection mark, and the inspection mark is formed in the etching step. Therefore, processing along the planned dividing lines and the formation of the inspection mark can simultaneously be executed in the etching step.

When the wafer processing method includes the protective member forming step of forming the first protective member on the front surface before the processing step, and the transfer step of forming the second protective member on the back surface and peeling off the first protective member from the front surface after the inspection step, the defective portion needs to be identified from the front surface side even when the inspection step is executed from the back surface side. However, identifying the defective portion on the basis of the characteristic point allows the defective portion to be recognized even from the front surface.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating an example of a wafer;

FIG. 2 is a sectional view illustrating a state in which the wafer is held by a holding table;

FIG. 3 is a perspective view illustrating a state in which a first protective member is stuck to a front surface of the wafer and the wafer is supported by a ring-shaped frame;

FIG. 4 is a sectional view illustrating an example of a processing step using a laser processing apparatus;

FIG. 5 is a perspective view illustrating an example of a divided wafer;

FIG. 6 is a sectional view illustrating a state in which the wafer is held by a holding table formed of a transparent body and a planned dividing line is detected from a lower side of the transparent body to execute processing;

FIG. 7 is a sectional view illustrating an example of an inspection step in which inspection is executed from a back surface side;

FIG. 8 is a plan view illustrating an example of a defective device;

FIG. 9 is a sectional view illustrating a state in which a second protective member is stuck in a transfer step;

FIG. 10 is a sectional view illustrating a state in which the first protective member is peeled off in the transfer step;

FIG. 11 is a plan view illustrating the front surface side of the wafer after execution of the transfer step;

FIG. 12 is a plan view illustrating an example of the wafer in which inspection marks are formed on the back surface;

FIG. 13 is a plan view illustrating an example of the wafer in which alignment marks are formed on the front surface;

FIG. 14 is a sectional view illustrating an example of a processing step using a cutting apparatus;

FIG. 15 is a sectional view illustrating a state in which a protective film is formed on the back surface of the wafer;

FIG. 16 is a sectional view illustrating a state in which the protective film is removed to expose the planned dividing lines;

FIG. 17 is a sectional view illustrating an example of a processing step in which the wafer is divided by plasma etching;

FIG. 18 is a sectional view illustrating a state in which the protective film is removed;

FIG. 19 is a plan view illustrating a state in which inspection mark-corresponding removed parts are formed in the protective film;

FIG. 20 is a plan view illustrating the wafer in which an orientation flat is formed;

FIG. 21 is a plan view illustrating a center of the wafer in which a notch is formed;

FIG. 22 is a plan view illustrating processing of obtaining the center of the wafer in which the notch is formed;

FIG. 23 is a plan view illustrating the center of the wafer in which the orientation flat is formed;

FIG. 24A to FIG. 24E are plan views illustrating processing of obtaining the center of the wafer in which the orientation flat is formed; and

FIG. 25 is a sectional view illustrating a state in which the back surface of the wafer is ground.

### DETAILED DESCRIPTION OF THE PREFERRED EMBODIMENTS

### 1 First Embodiment

(1-1) Protective Member Forming Step

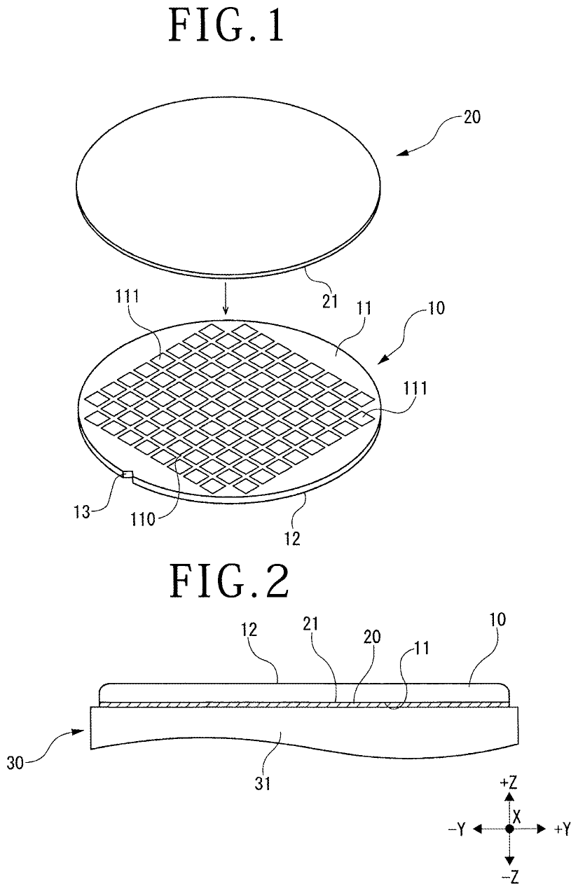

As illustrated in FIG. 1, a front surface 11 of a wafer 10 is stuck to an adhesive surface 21 of a first protective member 20. Here, devices 111 each having a circuit pattern are formed in respective regions marked out by a plurality of planned dividing lines 110 on the front surface 11 of the wafer 10, and the first protective member 20 plays a role in protecting the devices 111. A notch 13 indicating a direction of crystal orientation is formed at a circumferential edge part of the wafer 10.

(1-2) Holding Step

As illustrated in FIG. 2, the front surface 11 side of the wafer 10 is held under suction by a holding table 31 of a laser processing apparatus 30 with the interposition of the first protective member 20, and a back surface 12 of the wafer 10 is exposed upward.

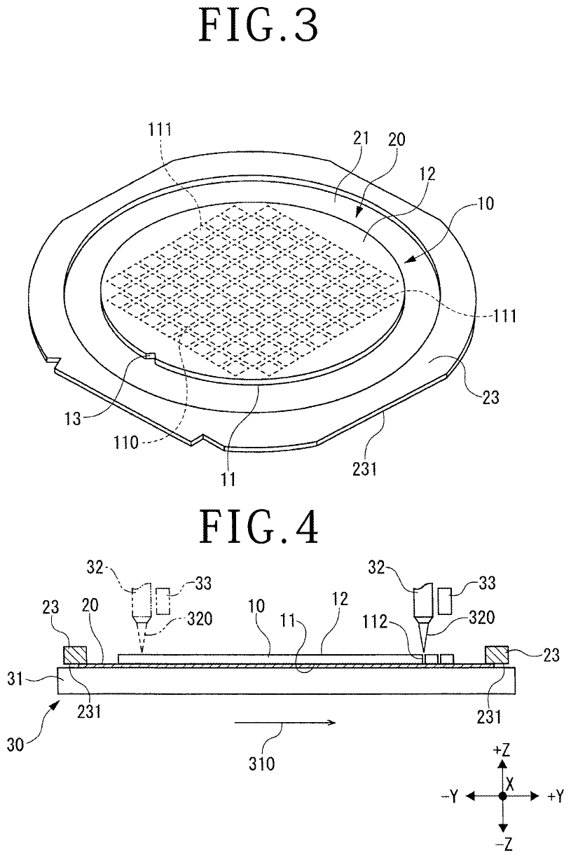

Instead of the sticking of the first protective member 20, pressure bonding of a resin sheet that does not have an adhesive layer may be executed, or a hard support wafer may be stuck with the interposition of wax or resin. Further, as illustrated in FIG. 3, by sticking the first protective member 20 with a larger diameter than the wafer 10 to the front surface 11 of the wafer 10 and sticking a lower surface 231 of a ring-shaped frame 23 to an outer circumferential part of the adhesive surface 21 of the first protective member 20, the wafer 10 may be supported by the frame 23 through the first protective member 20. In the following, the case of processing the wafer 10 supported by the frame 23 through the first protective member 20 will be described.

(1-3) Processing Step

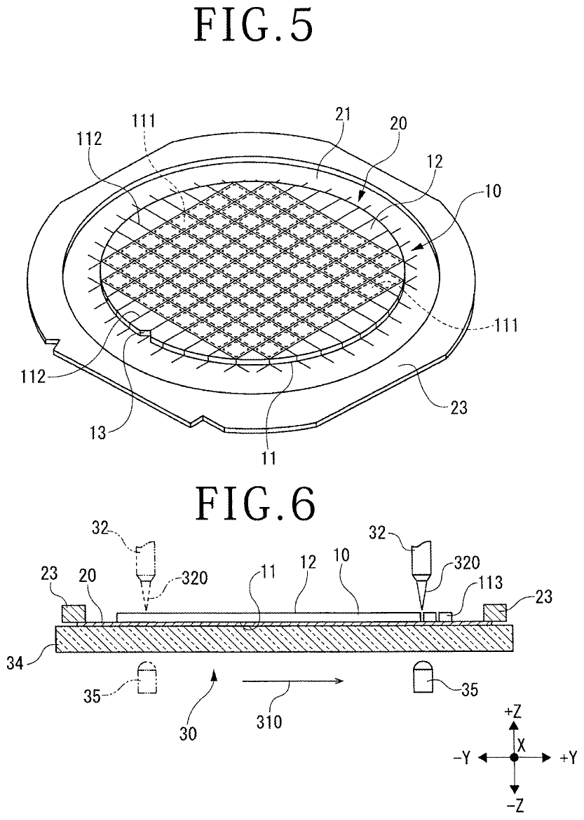

As illustrated in FIG. 4, the laser processing apparatus 30 includes a laser irradiation head 32 and an infrared camera 33 in addition to the holding table 31 illustrated in FIG. 2. In the present step, the front surface 11 is imaged by the infrared camera 33 from the back surface 12 side while the holding table 31 is moved in an X-axis direction, and one planned dividing line 110 illustrated in FIG. 3 is detected. Then, the laser irradiation head 32 and the holding table 31 are moved relative to each other in the X-axis direction while irradiation with laser light 320 with a wavelength having absorbability with respect to the wafer 10 is executed from the laser irradiation head 32 for the detected planned dividing line 110. Ablation processing is thus executed along the planned dividing line 110, and a dividing groove 112 that penetrates the wafer 10 is formed. Then, similar processing is executed while feed of the laser irradiation head 32 is executed in a Y-axis direction indicated by an arrow 310 at intervals of a distance between adjacent ones of the planned dividing lines 110. When the dividing grooves 112 have been formed along all the planned dividing lines 110 extending in the same direction, the holding table 31 is rotated by 90 degrees, and then similar ablation processing is executed. Thereupon, as illustrated in FIG. 5, the wafer 10 is split laterally and longitudinally to be divided into chips 113 having respective devices 111. Processed grooves that do not penetrate the wafer 10 and do not divide the wafer 10 may be formed instead of the dividing grooves 112, and thereafter, the wafer 10 may be divided into the chips 113 by applying an external force.

As illustrated in FIG. 6, in some cases, the front surface 11 side of the wafer 10 is held by a holding table 34 formed of a transparent body. In this case, the planned dividing line can be detected by disposing an imaging unit 35 under the holding table 34 and imaging the front surface 11. Therefore, the infrared camera is unnecessary in this case.

In the processing step, in some cases, a modified layer that is to act as an origin of division is formed inside the wafer 10 along the planned dividing line 110, by using the laser processing apparatus 30 and moving the laser irradiation head 32 and the holding table 31 relative to each other in a horizontal direction while executing irradiation with laser light with a wavelength having transmissibility with respect to the wafer 10. Also in this case, the modified layers are formed inside the wafer 10 along all the planned dividing lines 110. When the modified layers are thus formed inside the wafer 10, the wafer 10 is divided into individual chips having respective devices with use of the modified layers as the origins by grinding the back surface 12 to expose the modified layers or applying an external force to the modified layers later.

(1-4) Inspection Step

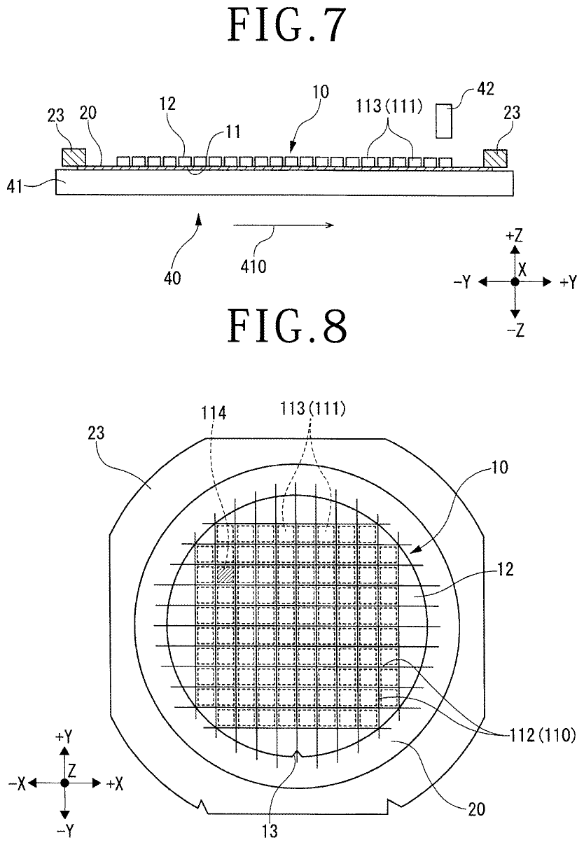

As illustrated in FIG. 7, an inspecting apparatus 40 includes an inspection table 41 on which the wafer 10 divided into the chips 113 is placed and an imaging unit 42 that images the wafer 10 placed on the inspection table 41 from above. The side of the first protective member 20 stuck to the front surface 11 of the wafer 10 is placed on the inspection table 41.

In the present step, the chips 113 are imaged from above while the inspection table 41 and the imaging unit 42 are moved relative to each other in a horizontal direction indicated by an arrow 410, and such defects as chipping, cracks, breakage, and holes are detected. In this relative movement, it is also possible to simultaneously image the chips 113 on a plurality of rows. All the chips 113 are imaged by executing reciprocation of this relative movement a plurality of times, and images for all the chips 113 are formed.

Then, the processing quality is inspected based on the images and, when the existence of a defective device is detected, the position thereof is stored in a storing part that is not illustrated. This position is stored on the basis of a characteristic point that the wafer 10 has. For example, the position of a defective device 114 illustrated in FIG. 8 is stored on the basis of the notch 13 formed in the wafer 10. For example, when the direction of a perpendicular line oriented from the notch 13 toward a center of the wafer 10 is defined as a Y direction and the direction orthogonal to the Y direction is defined as an X direction, the defective device 114 exists at a position that is displaced from the notch 13 in the −X direction by a distance corresponding to four devices and is displaced from the notch 13 in the +Y direction by a distance corresponding to eight devices. Therefore, in this case, the position of the defective device 114 is stored in the storing part as (−4, 8), for example. The inspection method is not limited thereto and can be changed as appropriate to inspection of electrical characteristics with use of a probe, or the like.

(1-5) Transfer Step

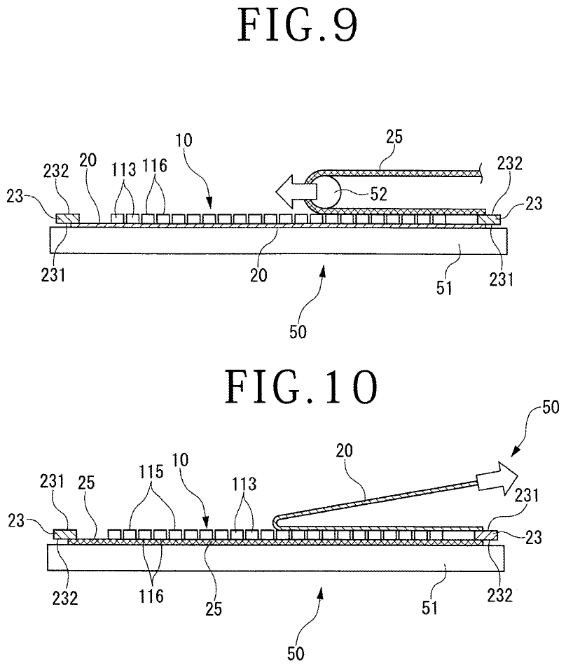

In the case of picking up, in the next step, the individual chips 113 formed by dividing the wafer 10 in the processing step, the chips 113 are held by a picking-up apparatus in the state in which the front surface side of the chips is oriented upward so as to have the front surface side to be held under suction, and therefore, the first protective member 20 needs to be peeled off before the picking-up. Further, also in the case of executing some kind of treatment for the front surface side, likewise, the first protective member 20 needs to be peeled off. For this purpose, a second protective member 25 is stuck to the back surface 12 side of the wafer 10, which has been divided into the chips 113 but still keeps the original shape as a whole, by using a transfer apparatus 50 illustrated in FIG. 9, and thereafter, the first protective member 20 is peeled off.

For example, the divided wafer 10 is held on a table 51 of the transfer apparatus 50 illustrated in FIG. 9 with the first protective member 20 being set on the lower side. Then, the second protective member 25 is stuck to an upper surface 232 of one end of the frame 23, and thereafter, the second protective member 25 is stuck to back surfaces 116 of the chips 113 while a roller 52 is rolled thereon. Then, the sticking is ended when the second protective member 25 has been stuck to the upper surface 232 of the other end of the frame 23.

Thereafter, as illustrated in FIG. 10, the side of the second protective member 25 is held on the table 51, an end part of the first protective member 20 is lifted up, and the end part is pulled toward the side of the other end part, thereby peeling off the first protective member 20. In this way, a front surface 115 of each chip 113 is exposed.

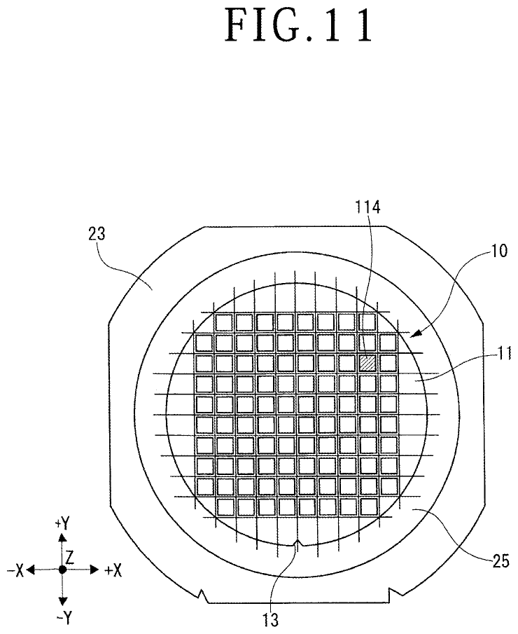

Also after the first protective member 20 is peeled off from the front surfaces 115 and the second protective member 25 is stuck to the back surfaces 116, as illustrated in FIG. 11, the position of the defective device 114 can be recognized as a position (4, 8) on the basis of the notch 13 as in the case of FIG. 8. Due to inversion of the front and back of the wafer 10, the plus or minus sign of the position in the X direction is inverted from that before the transfer illustrated in FIG. 8.

The chips 113 that have been divided and in which the side of the front surface 115 is exposed in this way are conveyed to the picking-up apparatus in the state in which they are stuck to the second protective member 25 or are conveyed to a treatment apparatus that executes treatment for the front surfaces. For example, the position information (4, 8) of the defective device 114 is transferred from the inspecting apparatus 40 to the picking-up apparatus. Then, in the picking-up apparatus, it becomes possible to execute processing of excluding the defective device 114 from the picking-up target, for example, based on the position information.

Accordingly, the defective portion can accurately be identified on the basis of the notch that is a characteristic point of the wafer even if, when the wafer is conveyed to a holding table of the picking-up apparatus, the wafer rotates from the state in which the wafer has been placed on the holding table of the inspecting apparatus and the center position deviates.

### 2 Second Embodiment

(2-1) Protective Member Forming Step

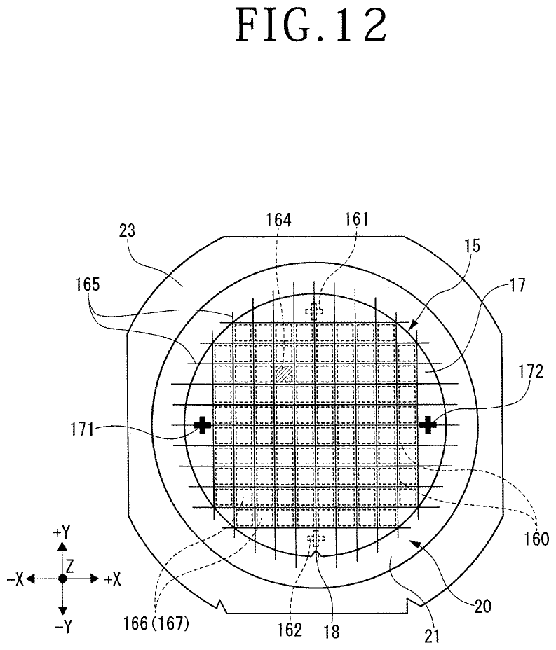

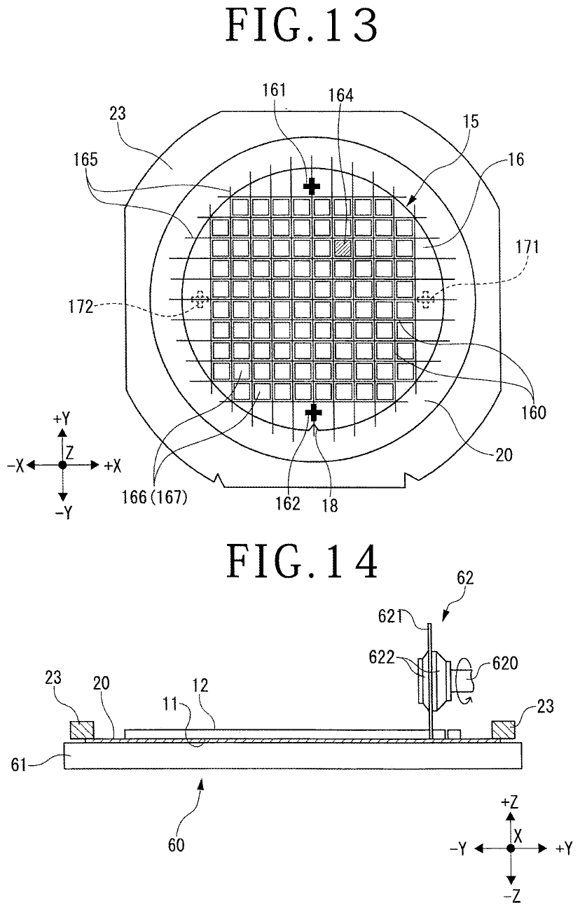

The present step may be similar to that illustrated in FIG. 2 of the first embodiment. Here, as illustrated in FIG. 12 and FIG. 13, the first protective member 20 with a larger diameter than a wafer 15 is stuck to a front surface 16 of the wafer 15, and the ring-shaped frame 23 is stuck to the outer circumferential part of the adhesive surface 21 of the first protective member 20, so that the wafer 15 is supported by the frame 23 through the first protective member 20. Here, as illustrated in FIG. 13, devices 166 are formed in respective regions marked out by a plurality of planned dividing lines 160 on the front surface 16 of the wafer 15, and the first protective member 20 plays a role in protecting the devices 166.

(2-2) Holding Step

A holding step is executed in a manner similar to that in the first embodiment, and the first protective member 20 side of the wafer 15 is held by the holding table 31 of the laser processing apparatus 30 as illustrated in FIG. 4.

(2-3) Processing Step

A first alignment mark 161 and a second alignment mark 162 are formed in regions in which no device is formed, on the front surface 16 of the wafer 15 illustrated in FIG. 13. A positional relation between the first alignment mark 161, the second alignment mark 162, and one planned dividing line 160 to be detected first is stored in advance in a storing part that is not illustrated. By detecting, by the infrared camera 33, the first alignment mark 161 and the second alignment mark 162 of the wafer 15 held by the holding table 31 illustrated in FIG. 4 with the interposition of the first protective member 20, the position of the planned dividing line 160 to be processed can be identified, and the laser irradiation head 32 can be positioned above the planned dividing line 160. Each alignment mark may be not a pattern formed in each chip, and a special mark formed for alignment like the first alignment mark 161 and the second alignment mark 162, or a pattern of the device formed in each chip may be used. In the case of using the pattern of the device formed in each chip, it is preferable to store positional relations in association with the row and the column of the device such that the position of a chip identified as a defective chip may be prevented from deviating.

Then, dividing grooves or modified layers are formed along all the planned dividing lines 160 as with the first embodiment by moving the holding table 31 and the laser irradiation head 32 relative to each other in a horizontal direction. For example, as illustrated in FIG. 12 and FIG. 13, the wafer 15 is divided into individual chips 167 having respective devices 166 when dividing grooves 165 that penetrate the wafer 15 are formed.

Although the first alignment mark 161 and the second alignment mark 162 are formed on the front surface 16 of the wafer 15, in a later inspection step, inspection is executed from the side of a back surface 17 of the wafer 15, and therefore, it is impossible to identify a defective device on the basis of the first alignment mark 161 and the second alignment mark 162. To cope with the problem, a first inspection mark 171 and a second inspection mark 172 having a predetermined positional relation with the first alignment mark 161 and the second alignment mark 162 are formed on the back surface 17 to allow the position of a defective device to be identified on the basis of the first inspection mark 171 and the second inspection mark 172. The first inspection mark 171 and the second inspection mark 172 can be formed by forming an origin of division inside the wafer 15 by ablation processing through irradiation with laser light from the laser irradiation head 32 or internal processing through irradiation with a laser beam with a wavelength having transmissibility with respect to the wafer 15, and then causing cracks to extend from the origin of division toward the front and back surfaces.

(2-4) Inspection Step

An inspection step is executed by imaging similar to that of the first embodiment. Further, when the existence of a defective device is detected, the position thereof is stored on the basis of the positions of the first inspection mark 171 and the second inspection mark 172. For example, a defective device 164 illustrated in FIG. 12 exists at a position displaced from the first inspection mark 171 by a distance corresponding to four devices in the +X direction and by a distance corresponding to three devices in the +Y direction. Hence, the position thereof is stored as (+4, +3). The first inspection mark 171 exists at a position displaced from the first alignment mark 161 by −6 in the −X direction and by −6 in the −Y direction. Hence, the position of the defective device 164 is (−6+4, −6+3)=(−2, −3) when the first alignment mark 161 is deemed as the basis, and this information is stored in the storing part. As above, by forming an inspection mark like the first inspection mark 171 and the second inspection mark 172 on the back surface 17, the position on the basis of the alignment mark can be identified without imaging the front surface 16 side.

(2-5) Transfer Step

A transfer step is executed in a manner similar to that in the first embodiment. After the end of the transfer step, the divided wafer 15 is conveyed to a picking-up apparatus, for example. In the picking-up apparatus, the position of the defective device 164 is recognized by position information of the above-described (−2, −3), and this position is excluded from the picking-up target. Accordingly, when the wafer is conveyed to a holding table of the picking-up apparatus, even if the wafer rotates from the state in which the wafer has been placed on the holding table of the inspecting apparatus and the center position deviates, the defective portion can accurately be identified on the basis of the alignment mark that is a characteristic point of the wafer.

### 3 Third Embodiment

(3-1) Protective Member Forming Step

The present step may be similar to that illustrated in FIG. 2 of the first embodiment. Here, as illustrated in FIG. 3, the first protective member 20 with a larger diameter than the wafer 10 is stuck to the front surface 11 of the wafer 10, and the ring-shaped frame 23 is stuck to the outer circumferential part of the adhesive surface 21 of the first protective member 20, so that the wafer 10 is supported by the frame 23 through the first protective member 20.

(3-2) Holding Step

As illustrated in FIG. 14, the first protective member 20 is held on a holding table 61 of a cutting apparatus 60. This exposes the back surface 12 side of the wafer 10. The cutting apparatus 60 includes a cutting unit 62. The cutting unit 62 includes a cutting blade 621 that is mounted to a tip part of a spindle 620 and clamped by a pair of flanges 622, and can move in the Y-axis direction and a Z-axis direction. Further, although not illustrated, the cutting apparatus 60 includes an infrared camera for detecting the planned dividing lines 110 (see FIG. 3) on the front surface 11 side. Moreover, when the holding table 61 is configured by a transparent body, a camera may be disposed under the holding table 61 instead of the infrared camera.

(3-3) Processing Step

In the present step, the front surface 11 is imaged by the infrared camera from the back surface 12 side while the holding table 61 is moved in a horizontal direction indicated by an arrow 611, and one planned dividing line 110 illustrated in FIG. 3 is detected. Then, the cutting blade 621 is positioned, while being rotated, above the planned dividing line 110. Then, while the holding table 61 is moved in the X-axis direction, the cutting blade 621 is made to cut into the wafer 10 in such a manner that a lower end of the cutting blade 621 reaches the first protective member 20. The planned dividing line 110 is thus cut. Further, the planned dividing lines 110 extending in the same direction are all cut by similarly executing cutting while feeding the cutting blade 621 in the -Y direction at intervals of a distance between adjacent ones of the planned dividing lines 110. Moreover, the holding table 61 is rotated by 90 degrees, and then similar cutting is executed. Accordingly, the wafer 10 is cut laterally and longitudinally along all the planned dividing lines 110 to be divided into individual chips 113 having respective devices 111.

The subsequent inspection step and transfer step are executed in a manner similar to those in the first embodiment or the second embodiment. That is, in the inspection step, the position of a defective device may be recognized on the basis of the notch 13 illustrated in FIG. 8. Alternatively, when the first alignment mark 161 and the second alignment mark 162 illustrated in FIG. 12 are formed, the first inspection mark 171 and the second inspection mark 172 having a predetermined positional relation with them may be formed, and the position of a defective device may be recognized on the basis of such marks.

The cutting apparatus 60 illustrated in FIG. 14 can be used for the formation of the first inspection mark 171 and the second inspection mark 172. Specifically, the holding table 61 of the cutting apparatus 60 is caused to hold the first protective member 20 side, and the cutting blade 621 is positioned above a position at which the first inspection mark 171 or the second inspection mark 172 is to be formed. Then, the cutting blade 621 is lowered, while being rotated, without the holding table 61 being moved, and a groove extending in the X direction, for example, is formed by what is generally called chopper cutting. Next, the holding table 61 is rotated by 90 degrees, and thereafter, the cutting blade 621 is moved to the position of the groove extending in the X direction. Then, the cutting blade 621 being rotated is lowered to form a groove extending in the Y direction by chopper cutting. In this manner, the first inspection mark 171 and the second inspection mark 172 with a cross shape can be formed.

The inspection step and the transfer step are executed in a manner similar to those in the first embodiment or the second embodiment.

### 4 Fourth Embodiment

(4-1) Protective Member Forming Step

The present step may be similar to that illustrated in FIG. 2 of the first embodiment. Here, as illustrated in FIG. 3, the first protective member 20 with a larger diameter than the wafer 10 is stuck to the front surface 11 of the wafer 10, and the ring-shaped frame 23 is stuck to the outer circumferential part of the adhesive surface 21 of the first protective member 20, so that the wafer 10 is supported by the frame 23 through the first protective member 20.

(4-2) Holding Step

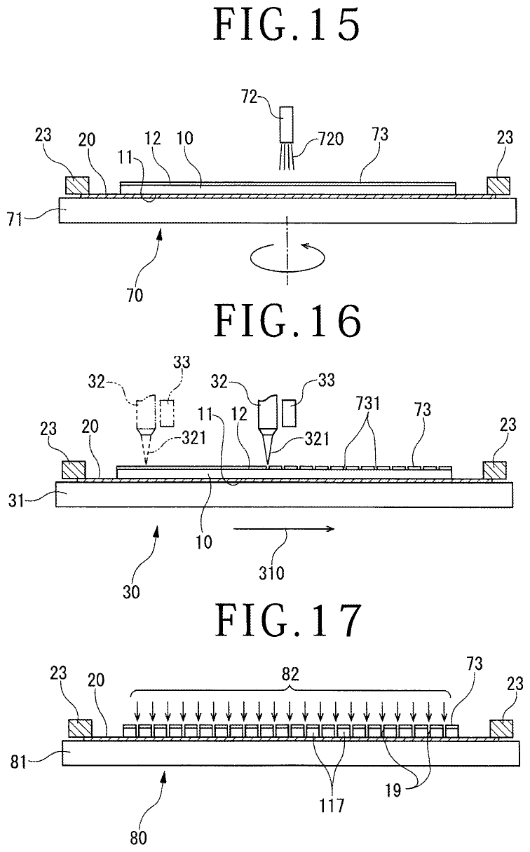

As illustrated in FIG. 15, the first protective member 20 side of the wafer 10 is held on a holding table 71 that can rotate in a protective film forming apparatus 70. This exposes the back surface 12 side of the wafer 10. The protective film forming apparatus 70 includes a nozzle 72 for ejecting liquid resin besides the holding table 71.

(4-3) Processing Step

(4-3-1) Protective Film Forming Step

As illustrated in FIG. 15, the holding table 71 that holds thereon the wafer 10 with the interposition of the first protective member 20 is rotated. In addition, the nozzle 72 is positioned above the center of the wafer 10, and liquid resin 720 is ejected from the nozzle 72. This causes spin coating of the liquid resin 720 on the back surface 12 of the wafer 10, so that the entire back surface 12 is coated with a protective film 73. Resin may be supplied in a spray manner instead of the liquid resin, or the protective film 73 may be formed by supplying powder resin and melting it through heat application or sticking sheet-shaped resin.

(4-3-2) Exposure Step

Next, the wafer 10 in which the back surface 12 is coated with the protective film 73 is conveyed to the laser processing apparatus 30, and the first protective member 20 side is held on the holding table 31 as illustrated in FIG. 16. This laser processing apparatus 30 is configured similarly to the laser processing apparatus 30 illustrated in FIG. 4.

As illustrated in FIG. 16, in the state in which the first protective member 20 side is held on the holding table 31, the front surface 11 is imaged by the infrared camera 33 from the back surface 12 side while the holding table 31 is moved in a horizontal direction indicated by the arrow 310, and one planned dividing line 110 illustrated in FIG. 3 is detected. Then, the laser irradiation head 32 and the holding table 31 are moved relative to each other in a horizontal direction while irradiation with laser light 321 with a wavelength having absorbability with respect to the protective film 73 is executed from the laser irradiation head 32 for the detected planned dividing line 110. Ablation processing of the protective film 73 is thus executed along the planned dividing line 110 to form a groove 731, and the portion corresponding to the planned dividing line 110 on the back surface 12 of the wafer 10 is exposed. Then, similar processing is executed while feed of the laser irradiation head 32 is executed at intervals of a distance between adjacent ones of the planned dividing lines 110. When the grooves 731 have been formed along all the planned dividing lines 110 extending in the same direction, the holding table 31 is rotated by 90 degrees, and then similar ablation processing is executed. Thereupon, the protective film 73 is split laterally and longitudinally by the grooves 731, and all the planned dividing lines 110 are exposed.

The exposure step can be executed by using the cutting apparatus 60 illustrated in FIG. 14 and making the cutting blade 621 cut into the protective film 73. In this case, because cutting water is used, the back surface 12 of the wafer 10 is coated with a non-water-soluble protective film in the protective film forming step.

(4-3-3) Etching Step

Next, as illustrated in FIG. 17, the first protective member 20 side of the wafer 10 is held on a holding table 81 of a plasma etching apparatus 80. Then, the holding table 81 and the wafer 10 held by it are moved into a chamber, and an etching gas 82 is introduced from the upper side with use of the divided protective film 73 as a mask. Etching is thus executed along the planned dividing lines 110 of the wafer 10, and dividing grooves 119 that penetrate the wafer 10 are formed along the planned dividing lines 110. Accordingly, the wafer 10 is divided into individual chips 117.

(4-3-4) Protective Film Removal Step

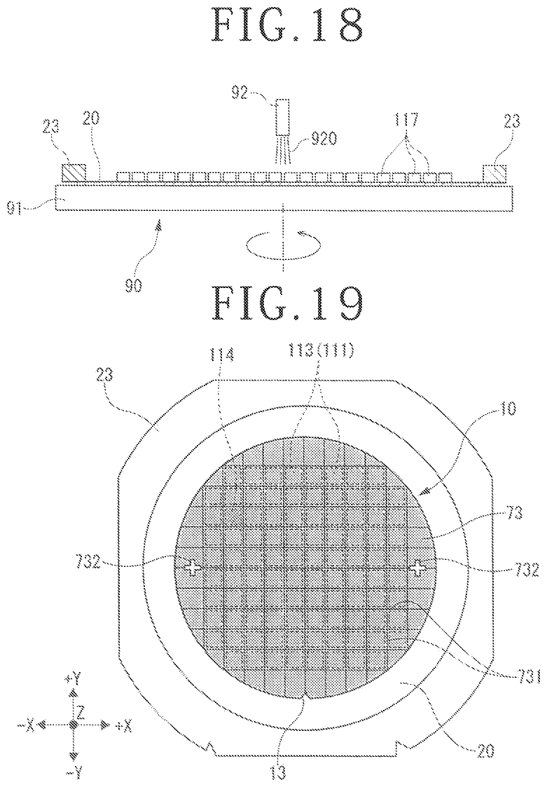

Next, the protective film is removed as illustrated in FIG. 18. For example, when the protective film is formed of water-soluble resin, the first protective member 20 side of the wafer 10 is held on a holding table 91 of a cleaning apparatus 90, and water 920 is jetted from a nozzle 92 to remove the protective film 73. When non-water-soluble resin is used as the protective film 73, the protective film is removed by chemical cleaning. The protective film can be removed also by asking.

When the protective film is an oxide film or a metal film, a transition to the next step is made without removal thereof.

The subsequent inspection step and transfer step are executed similarly to the first embodiment or the second embodiment.

### 5 Fifth Embodiment

(5-1) Protective Member Forming Step

The present step is executed in a manner similar to that in the third embodiment.

(5-2) Holding Step

The present step is also executed in a manner similar to that in the third embodiment.

(5-3) Processing Step

(5-3-1) Protective Film Forming Step

The present step is also executed in a manner similar to that in the fourth embodiment illustrated in FIG. 15.

(5-3-2) Exposure Step

The present step is also executed in a manner similar to that in the fourth embodiment illustrated in FIG. 16.

(5-3-3) Inspection Mark-Corresponding Removed Part Forming Step

In the present step, in order to form, in the wafer 10, inspection marks that serve as the basis for identifying the position of a defective device in a later inspection step, inspection mark-corresponding removed parts 732 are formed at positions that do not face any devices 111 in the protective film 73, as illustrated in FIG. 19, for example, by laser ablation through laser irradiation from the laser irradiation head 32.

(5-3-4) Etching Step

The present step is executed in a manner similar to that in the fourth embodiment illustrated in FIG. 17. Here, because the inspection mark-corresponding removed parts 732 have been formed in the inspection mark-corresponding removed part forming step, etching is executed not only along the planned dividing lines 110 but also at corresponding parts exposed at the inspection mark-corresponding removed parts 732 on the back surface 12 of the wafer 10. As a result, inspection marks corresponding to the inspection mark-corresponding removed parts 732 are formed on the back surface 12 of the wafer 10.

(5-3-5) Protective Film Removal Step

The present step is executed in a manner similar to that in the fourth embodiment illustrated in FIG. 18.

In the subsequent inspection step and transfer step, the position of a defective device is identified on the basis of the inspection marks formed in the etching step.

### 6 Sixth Embodiment

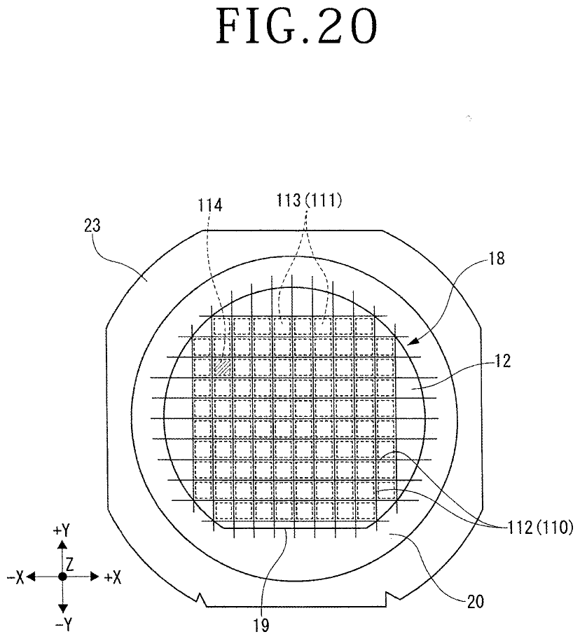

In a wafer 18 illustrated in FIG. 20, an orientation flat 19 is formed as a mark indicating the crystal orientation. Also in this wafer 18, a method similar to those of the above-described second to fifth embodiments can be employed. However, in the case of identifying the defective device 114 on the basis of the orientation flat 19 in the inspection step and the transfer step, for example, a center of the orientation flat 19 in the X direction is employed as the basis, and the position of the defective device 114 is identified based on displacement from the basis. In the wafer 18 illustrated in FIG. 20, the position of the defective device 114 can be represented as (−4, +8).

### 7 Seventh Embodiment

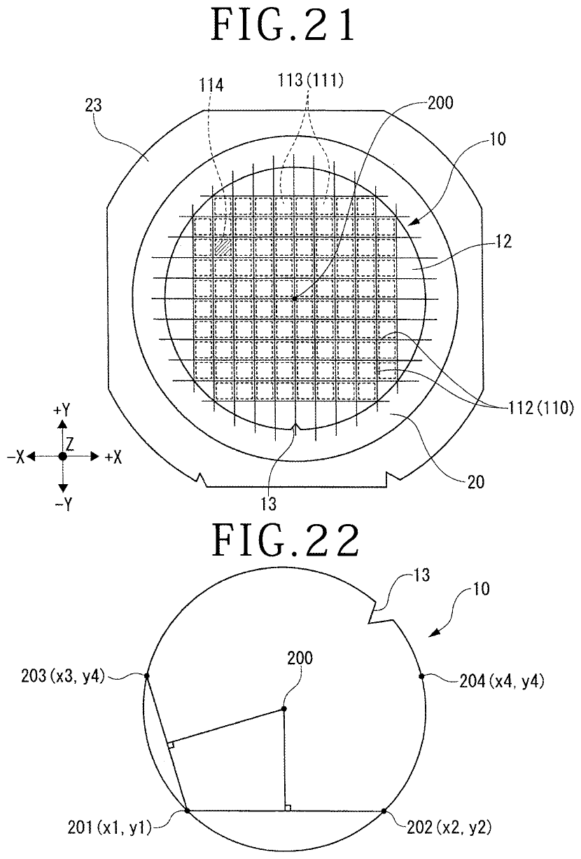

In the case of inspecting the processing quality of the wafer 10, illustrated in FIG. 1, in which the notch 13 is formed, a center 200 of the wafer 10 illustrated in FIG. 21 may be used as a characteristic point in the inspection step and the transfer step. To obtain the position of the center 200 of the wafer 10, for example, imaging by an imaging part that is not illustrated is executed from above while the wafer 10 is moved in the X-axis direction, and coordinates (x1, y1) and (x2, y2) of two points 201 and 202 that are illustrated in FIG. 22 and at which a change in height or luminance is detected are stored in a storing part. Next, the wafer 10 is moved in the X-axis direction and the Y-axis direction relative to the imaging part, and coordinates (x3, y3) and (x4, y4) of two points 203 and 204 at which a change in height or luminance is detected are stored in the storing part. Then, for example, a perpendicular bisector 205 of a line that links the point 201 and the point 202 is drawn, and a perpendicular bisector 206 of a line that links the point 201 and the point 203 is drawn. The intersection between the perpendicular bisector 205 and the perpendicular bisector 206 is the center 200.

In the case of identifying the position of the defective device 114 on the basis of the center 200 in the inspection step and the transfer step, the position of the defective device 114 is represented as (−4, 3) because the defective device 114 exists at a position displaced from the center 200 by 4 in the −X direction and by 3 in the +Y direction as illustrated in FIG. 21. As above, by using the center 200 of the wafer 10 as a characteristic point, the position of the defective device 114 can be recognized even from the back surface 12.

### 8 Eighth Embodiment

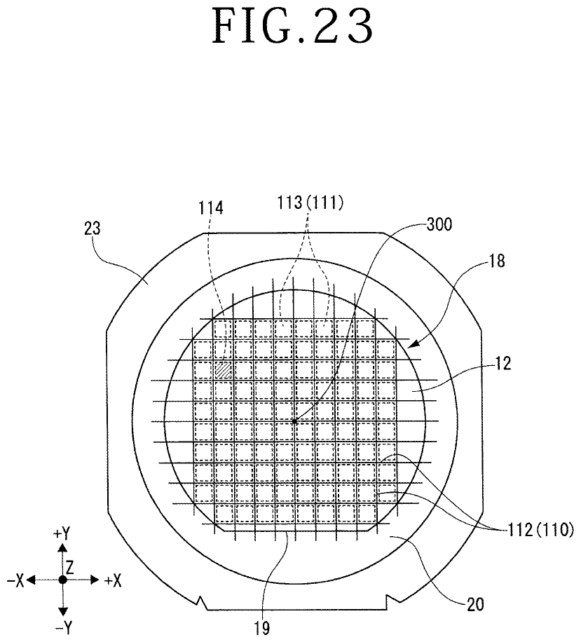

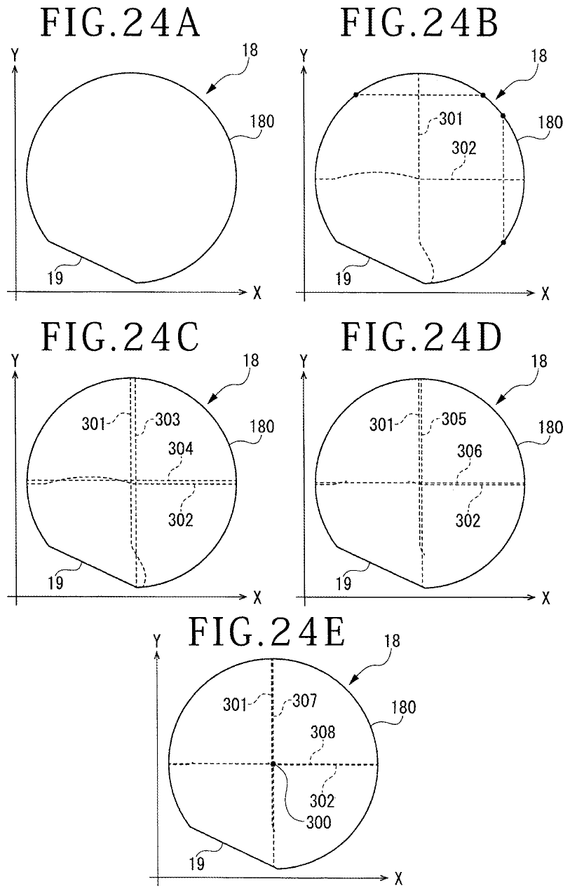

Also in the case of inspecting the processing quality of the wafer 18, illustrated in FIG. 20, in which the orientation flat 19 is formed, a center 300 of the wafer 18 illustrated in FIG. 23 can be used as a characteristic point in the inspection step and the transfer step. To obtain the position of the center 300 of the wafer 18, for example, imaging by an imaging part that is not illustrated is executed from above while the wafer 18 is moved in the X-axis direction and the Y-axis direction relative to the imaging part, and positions at which a change in height or luminance is detected are plotted in an X-Y plane coordinate system to draw an outer shape line 180 of the wafer 18 as illustrated in FIG. 24A.

Next, as illustrated in FIG. 24B, center coordinates between two points opposed in the X-axis direction in the plots that configure the outer shape line 180 of the wafer 18 are all obtained and plotted, and a line 301 is obtained by linking all the plots. Similarly, center coordinates between two points opposed in the Y-axis direction in the plots that configure the outer shape line 180 of the wafer 18 are all obtained and plotted, and a line 302 is obtained by linking all the plots.

The line 301 and the line 302 are affected by the orientation flat 19 and hence become line segments that partly curve. Accordingly, it is impossible to deem the intersection between the line 301 and the line 302 as the center of the wafer 18. Although, here, all center coordinates in the X-axis direction and the Y-axis direction are calculated from the outer shape line 180 of the wafer 18, all the center coordinates do not necessarily need to be calculated, and changes can be made as appropriate according to the calculation accuracy and so forth.

Next, as illustrated in FIG. 24C, an average value of the X-coordinate of the plots that configure the line 301 is calculated, and an average line 303 that passes through the X-coordinate of this average value and is parallel to the Y-axis is drawn. As a result, plots with a smaller X-coordinate than the average value are located on the left side of the average line 303, and plots with a larger X-coordinate than the average value are located on the right side of the average line 303. Then, the number of plots located on the left side of the average line 303 and the number of plots located on the right side of the average line 303 are compared to each other, and the plots on the side of the smaller number of plots are all discarded. In FIG. 24C, the plots on the right side of the average line 303 are all discarded.

Similarly, an average value of the Y- coordinate of the plots that configure the line 302 is calculated, and an average line 304 that passes through the Y-coordinate of this average value and is parallel to the X-axis is drawn. As a result, plots with a larger Y-coordinate than the average value are located on the upper side of the average line 304, and plots with a smaller Y-coordinate than the average value are located on the lower side of the average line 304. Then, the number of plots located on the upper side of the average line 304 and the number of plots located on the lower side of the average line 304 are compared to each other, and the plots on the side of the smaller number of plots are all discarded. In FIG. 24C, the plots on the upper side of the average line 304 are all discarded.

Next, as illustrated in FIG. 24D, an average value of the X-coordinate of the plots that configure the line 301 excluding the discarded plots is calculated, and an average line 305 is drawn. Then, the numbers of plots on the left and right of the average line 305 are compared to each other, and the plots on the side of the smaller number of plots (right side of the average line 305) are all discarded. Similarly, an average value of the Y-coordinate of the plots that configure the line 302 excluding the discarded plots is calculated, and an average line 306 is drawn. Then, the numbers of plots on the upper and lower sides of the average line 306 are compared to each other, and the plots on the side of the smaller number of plots (upper side of the average line 306) are all discarded.

Through repetition of the calculation processing of the average line in this manner, the intersection between the average line of the line 301 and the average line of the line 302 comes closer to the center coordinates of the wafer 18. In the present embodiment, as illustrated in FIG. 24E, an intersection between average lines 307 and 308 obtained after two times of repetition of the above-described processing is deemed as a provisional center position of the wafer 18.

In the case of identifying the position of the defective device 114 on the basis of the center 300 in the inspection step and the transfer step, the position of the defective device 114 is represented as (−4, 3) because the defective device 114 exists at a position displaced from the center 300 by 4 in the −X direction and by 3 in the +Y direction as illustrated in FIG. 23. As above, by using the center 300 of the wafer 18 as a characteristic point, the position of the defective device 114 can be recognized even from the back surface 12.

The position of the center 200 of the wafer 10 in which the notch 13 is formed may be obtained by using this method.

### 9 Ninth Embodiment

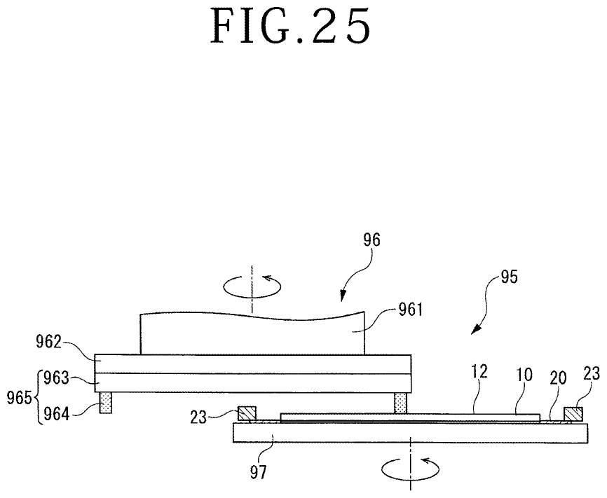

In the processing step of the above-described first to sixth embodiments, a thinning step of thinning the wafer 10 by using a grinding apparatus 95 illustrated in FIG. 25 may be executed before the wafer 10 is divided. The grinding apparatus 95 includes a holding table 97 that holds the wafer 10 thereon and can rotate and a grinding mechanism 96 that grinds the wafer 10 held by the holding table 97. The grinding mechanism 96 includes a spindle 961 that can rotate, a mount 962 attached to a lower end of the spindle 961, and a grinding wheel 965 attached to the mount 962. The grinding wheel 965 includes a base 963 fixed to the mount 962 and grinding abrasive stones 964 made to adhere to a lower surface of the base 963.

In the grinding apparatus 95, the wafer 10 is held by the holding table 97 with the interposition of the first protective member 20. Then, the holding table 97 rotates, and in addition, the grinding wheel 965 lowers while rotating. When the thus rotating grinding abrasive stones 964 get contact with the back surface 12 of the wafer 10, the back surface 12 is ground. Then, when the wafer 10 has been formed into a desired thickness, the grinding mechanism 96 is raised to end the grinding. After the wafer 10 is thus formed into the desired thickness, the wafer 10 is divided into individual chips 113 having respective devices 111, by using the laser processing apparatus 30 illustrated in FIG. 4, the cutting apparatus 60 illustrated in FIG. 14, or the plasma etching apparatus 80 illustrated in FIG. 17.

As above, in the present invention, in the inspection step of inspecting the processing quality from the back surface of the wafer, a defective portion is stored on the basis of a characteristic point that the wafer has, for example, a notch, an orientation flat, the center point of the wafer, an inspection mark, or the like. A design or the like that serves as the basis for identifying the position of a defective portion does not exist on the back surface, unlike on the front surface. However, by storing the position of a defective portion on the basis of the characteristic point that the wafer has, the position of the defective portion can be identified without imaging the front surface side.

The examples in which the processing method of the present invention is applied to processing of a wafer have been explained in the above-described embodiments. However, the present invention is not limited to processing of a wafer and can similarly be applied also to processing of a package substrate on which a plurality of chips are mounted on a front surface thereof.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method for processing a wafer having a front surface on which a pattern and a plurality of planned dividing lines are formed, along the planned dividing lines, the wafer processing method comprising:
a holding step of holding the front surface of the wafer by a holding table;
a processing step of detecting the planned dividing lines on the front surface from a side of the front surface through the holding table or from a side of a back surface by using an infrared camera and processing the wafer by using a processing unit from the side of the back surface along the planned dividing lines; and
an inspection step of placing the wafer on an inspection table and inspecting processing quality from the back surface after the processing step,
wherein a defective portion is stored on a basis of a characteristic point that the wafer has, in the inspection step.

2. The wafer processing method according to claim 1,
wherein the characteristic point is a notch, an orientation flat, or a center point of the wafer.

3. The wafer processing method according to claim 1, further comprising:
an inspection mark forming step of forming an inspection mark on the back surface by using the processing unit on a basis of an alignment mark formed on the front surface,
wherein the characteristic point is the inspection mark.

4. The wafer processing method according to claim 3,
wherein any of a dividing groove that divides the wafer, a processed groove that does not divide the wafer, or a modified layer formed inside the wafer is formed in the processing step and the inspection mark forming step.

5. The wafer processing method according to claim 3,
wherein the processing step includes
a protective film forming step of forming a protective film on the back surface of the wafer,
an exposure step of removing the protective film formed along the planned dividing lines, by using the processing unit, to expose the planned dividing lines after the protective film forming step, and
an etching step of executing plasma etching from the back surface to process the wafer along the planned dividing lines after the exposure step, and
the inspection mark forming step removes the protective film at a freely-selected position in a manner corresponding to a shape of the inspection mark, by using the processing unit, and forms the inspection mark on the back surface of the wafer in the etching step.

6. The wafer processing method according to claim 1, further comprising:
a protective member forming step of forming a first protective member on the front surface before the processing step; and
a transfer step of forming a second protective member on the back surface and peeling off the first protective member from the front surface after the inspection step.
